(19) United States
(12) Patent Application Publication
(10) Pub. No.: US 2026/0283053 A1
(43) Pub. Date: Sep. 17, 2026

(54) LAMINATE PASSIVE STRUCTURE WITH STAND-OFF FOR MULTILEVEL MODULE INTEGRATION

(71) Applicant: Qorvo US, Inc., Greensboro, NC (US)

(72) Inventors: Thomas Scott Morris, Lewisville, NC (US); Charles E. Carpenter, Orlando, FL (US); Yong-Jae Ko, Gwangju (KR)

(21) Appl. No.: 19/542,092

(22) Filed: Feb. 17, 2026

Related U.S. Application Data
(60) Provisional application No. 63/771,282, filed on Mar. 13, 2025.

(51) Int. Cl. H10W 90/00

(52) U.S. Cl. CPC H10W 90/724; H10W 90/00; H10W 90/726

(57) ABSTRACT

The present disclosure relates to a multi-level system-in-package (SIP) module featuring at least one laminate passive structure designed to provide stand-off relative to a module substrate for enhanced performance and/or a reduced footprint, and a process for manufacturing the same. In the disclosed multi-level SIP module, the laminate passive structure is attached to a top side of the module substrate and includes a component unit and multiple copper posts. The component unit has at least a laminate body, a bottom metal layer protruding vertically from a bottom surface of the laminate body, and a top metal layer embedded in the laminate body and configured to provide at least a portion of a passive component. The copper posts are connected to the bottom metal layer and extend towards the top side of the module substrate, which provides a stand-off space vertically between the component unit and the module substrate.

### RELATED APPLICATIONS

This application claims the benefit of provisional patent application Ser. No. 63/771,282, filed Mar. 13, 2025, the disclosure of which is hereby incorporated herein by reference in its entirety.

### FIELD OF THE DISCLOSURE

The present disclosure relates to a multi-level system-in-package (SIP) module that includes at least one laminate passive structure designed to provide stand-off relative to a module substrate for enhanced performance and/or a reduced footprint, and a process for manufacturing the multi-level SIP module including the at least one laminate passive structure.

### BACKGROUND

Electronic components have become ubiquitous in modern society. With the popularity of portable consumer electronic products, such as smart phones, tablet computers, and so forth, the demand for microelectronic devices that achieve higher electronic density within a smaller footprint is continually increasing.

One approach for advancement is to utilize the full volume of a package to enable greater integration, such as three-dimensional (3D) package integration. A system-in-package (SIP) module with the 3D package integration is capable of significantly reducing the footprint. However, the enhanced integration of the SIP module will also increase the density and complexity of electrical routing within a module substrate of the SIP module. Consequently, passive components embedded in the module substrate may experience performance degradation. In addition, the SIP module with the 3D package may lead to a relatively large overall thickness of the final product. In particular, when the SIP module incorporates double-sided packaging in addition to the 3D package integration, the overall thickness of the final product will increase further, which is undesirable for portable devices.

Accordingly, to achieve increased electronic density and functionality within a low-profile product having a small footprint, and to enhance the electronic performance of the product, it is therefore an object of the present disclosure to provide an improved design of a SIP module and a process for making the same.

### SUMMARY

The present disclosure relates to a multi-level system-in-package (SIP) module that includes at least one laminate passive structure, designed to provide stand-off relative to a module substrate for enhanced performance and/or a reduced footprint, as well as a process for manufacturing the same. According to one embodiment, the disclosed multi-level SIP module includes a module substrate, a laminate passive structure mounted to a top side of the module substrate, and at least one top component attached to the top side of the module substrate. Herein, the laminate passive structure includes a number of copper posts and a component unit that has at least a laminate body, a top metal layer, and a bottom metal layer. The bottom metal layer is positioned about a bottom side of the component unit and protrudes vertically from a bottom surface of the laminate body, while the top metal layer is positioned about a top side of the component unit and configured to provide at least a portion of a passive component. The copper posts are connected to the bottom metal layer on the bottom side of the component unit and extend towards the top side of the module substrate, which provides a stand-off space that is vertically between the component unit and the module substrate.

In one embodiment of the multi-level SIP module, the top metal layer is embedded in the laminate body and exposed through the laminate body, and the top side of the component unit is a flat surface composed of a top surface of the laminate body and a top surface of the top metal layer.

In one embodiment of the multi-level SIP module, the top metal layer is formed by an embedded trace substrate (ETS) technology and at least includes patterned metal features.

In one embodiment of the multi-level SIP module, the bottom metal layer at least includes bottom metal pads, each of which is configured to accommodate a corresponding one of the copper posts and protrudes vertically from the bottom surface of the laminate body.

In one embodiment of the multi-level SIP module, the component unit further includes one or more internal metal layers completely embedded in the laminate body and vertically between the top metal layer and the bottom metal layer.

In one embodiment of the multi-level SIP module, a number of the one or more internal metal layers is between 1 and 7.

In one embodiment of the multi-level SIP module, a thickness of the component unit is between 70 μm and 220 μm.

In one embodiment of the multi-level SIP module, an end surface of each of the copper posts is covered by a surface finish, which is designed to ensure that the end surface of each of the copper posts is solderable.

In one embodiment of the multi-level SIP module, the surface finish comprises one or more of gold (Au), silver (Ag), tin (Sn), nickel gold (NiAu), and nickel palladium gold (NiPdAu).

In one embodiment of the multi-level SIP module, each of the copper posts is connected to a corresponding metal pad at the top side of the module substrate through a solder joint, which is positioned vertically between the surface finish on the end surface of each of the copper posts and the corresponding metal pad at the top side of the module substrate.

In one embodiment of the multi-level SIP module, a combined height of each of the copper posts, the surface finish on the end surface of each of the copper posts, and a corresponding solder joint is the same and is between 25 μm and 150 μm.

According to one embodiment, the multi-level SIP module further includes a top mold compound. The top mold compound is formed on the top side of the module substrate to fully encapsulate the at least one top component and to surround the laminate passive structure.

In one embodiment of the multi-level SIP module, the at least one top component includes a first top component, which is positioned in the stand-off space vertically between the bottom side of the component unit and the top side of the module substrate and surrounded by the copper post. A gap between the bottom side of the component unit and a top surface of the first top component has a vertical distance between 10 μm and 50 μm and is filled with the top mold compound.

In one embodiment of the multi-level SIP module, the at least one top component further includes a second top component, which is positioned horizontally outside the laminate passive structure.

In one embodiment of the multi-level SIP module, the at least one top component is positioned horizontally outside the laminate passive structure. No electronic component is surrounded by the copper posts and positioned vertically between the bottom side of the component unit and the top side of the module substrate. A gap between the bottom side of the component unit and the top side of the module substrate has a vertical distance between 20 μm and 100 μm and is filled with the top mold compound.

In one embodiment of the multi-level SIP module, the laminate passive structure further includes a stiffening layer, which is formed over the component unit to encapsulate the top metal layer of the component unit. A top surface of the laminate passive structure is a top surface of the stiffening layer, and a side surface of the laminate passive structure is a combination of a side surface of the component unit and a side surface of the stiffening layer. The top mold compound at least surrounds and underfills the laminate passive structure without covering the top surface of the laminate passive structure, wherein the laminate passive structure does not vertically extend beyond a top surface of the top mold compound.

According to one embodiment, the multi-level SIP module further includes a module shielding structure. Herein, the top surface of the top mold compound and the top surface of the laminate passive structure are coplanar. The module shielding structure directly and continuously covers a combination of the top surface of the top mold compound and the top surface of the laminate passive structure, and a combination of a side surface of the top mold compound and a side surface of the module substrate.

According to one embodiment, the multi-level SIP module further includes at least one bottom component and a number of bump structures. Herein, the at least one bottom component and the bump structures are attached to a bottom side of the module substrate, which is opposite from the top side of the module substrate.

According to one embodiment, the multi-level SIP module further includes a bottom mold compound. The bottom mold compound surrounds each of the bump structures without covering an end surface of each of the bump structures. A bottom surface of the bottom mold compound and the end surface of each of the bump structures are coplanar. The bottom mold compound at least surrounds the at least one bottom component, and the at least one bottom component does not vertically extend beyond the bottom mold compound.

In one embodiment of the multi-level SIP module, the laminate passive structure has a height between 100 μm and 350 μm.

According to one embodiment, a communication device includes a control system, a baseband processor, receive circuitry, and transmit circuitry. Herein, at least one or any combination of the control system, the baseband processer, the transmit circuitry, and the receive circuitry is implemented in a multi-level SIP module, which includes a module substrate, a laminate passive structure, and at least one top component. The laminate passive structure and the at least one top component are attached to a top side of the module substrate. The laminate passive structure includes a number of copper posts and a component unit that has at least a laminate body, a top metal layer, and a bottom metal layer. Herein, the bottom metal layer is positioned about a bottom side of the component unit and protrudes vertically from a bottom surface of the laminate body, while the top metal layer is positioned about a top side of the component unit and configured to provide at least a portion of a passive component. The copper posts are connected to the bottom metal layer on a bottom side of the component unit and extend towards the top side of the module substrate, which provides a stand-off space that is vertically between the component unit and the module substrate.

According to one embodiment, a method of manufacturing a multi-level SIP module starts with forming a laminate passive structure, which includes a component unit and a number of copper posts. The component unit has at least a laminate body, a top metal layer, and a bottom metal layer. Herein, the bottom metal layer is positioned about a bottom side of the component unit and protrudes vertically from a bottom surface of the laminate body, while the top metal layer is positioned about a top side of the component unit and configured to provide at least a portion of a passive component. The copper posts are connected to the bottom metal layer on a bottom side of the component unit. Next, at least one top component is attached to a top side of a module substrate. The laminate passive structure is then attached to the top side of the module substrate. Each of the copper posts extends from the bottom side of the component unit towards the top side of the module substrate, which provides a stand-off space that is vertically between the component unit and the module substrate.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIGS. 1A-1B illustrate an exemplary multi-level system-in-package (SIP) module that includes an exemplary laminate passive structure to provide stand-off relative to a module substrate according to some embodiments of the present disclosure.

FIG. 2 illustrates an alternative configuration of the multi-level SIP module according to some embodiments of the present disclosure.

FIG. 3 provides a flow diagram that illustrates an exemplary process for manufacturing the laminate passive structure according to some embodiments of the present disclosure.

FIGS. 4-10 illustrate steps associated with the manufacturing process of the laminate passive structure provided in FIG. 3.

FIG. 11 provides a flow diagram that illustrates an exemplary process for manufacturing the multi-level SIP module according to some embodiments of the present disclosure.

FIGS. 12-20 illustrate steps associated with the manufacturing process of the multi-level SIP module provided in FIG. 11.

FIG. 21 is a block diagram of a communication device, which may include the multi-level SIP module according to some embodiments of the present disclosure.

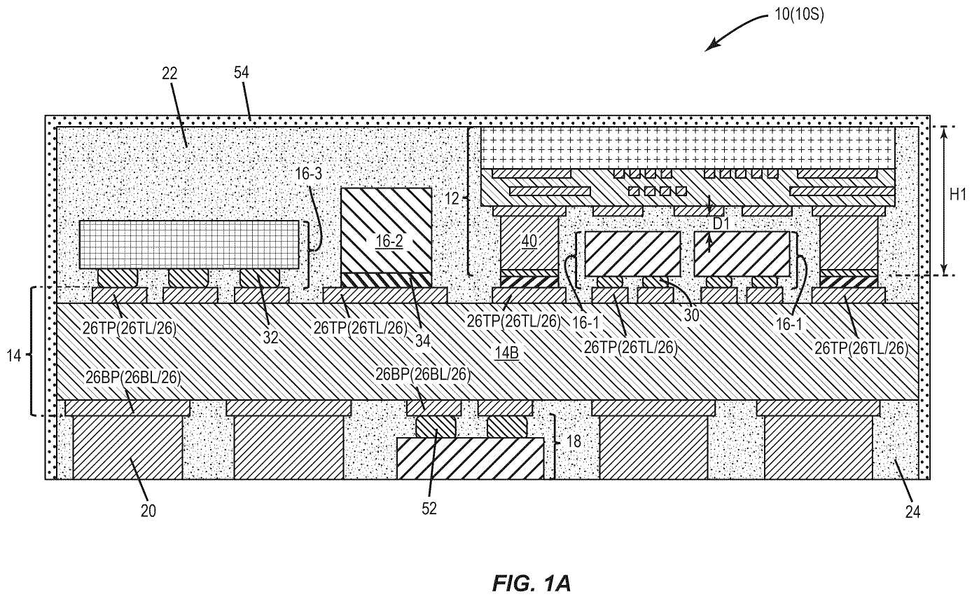

It will be understood that for clarity of illustration, FIGS. 1A-21 may not be drawn to scale.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to a multi-level system-in-package (SIP) module that includes at least one laminate passive structure designed to provide stand-off relative to a module substrate for enhanced performance and/or a reduced footprint, as well as a process for manufacturing the multi-level SIP module including the at least one laminate passive structure. In particular, the disclosed multi-level SIP module leverages three-dimensional (3D) packaging technology to enhance the integration density and utilizes the laminate passive structure to ensure a desired module thickness and/or improve electrical performance (e.g., achieving a high Q factor for an inductor coil implemented in the laminate passive structure).

FIGS. 1A-1B illustrate an exemplary multi-level SIP module 10 according to some embodiments. FIG. 1A is a cross-sectional diagram illustrating the multi-level SIP module 10, while FIG. 1B is an enlarged cross-sectional diagram illustrating a portion of the multi-level SIP module 10 including an exemplary laminate passive structure 12. For the purpose of this illustration, besides the laminate passive structure 12, the multi-level SIP module 10 also includes a module substrate 14, four top components 16 (e.g., two first top components 16-1, one second top component 16-2, and one third top component 16-3), one bottom component 18, four bump structures 20, a top mold compound 22, and a bottom mold compound 24. Herein, the top components 16 are formed on a top side of the module substrate 14, and the laminate passive structure 12 is formed on the top side of the module substrate 14 and caps the two first top components 16-1 to provide a stack-up structure. The bottom component 18 is formed on a bottom side of the module substrate 14, and the bump structures 20 are formed on the bottom side of the module substrate 14 and surround the bottom component 18. In different applications, the multi-level SIP module 10 may include fewer or more top components 16 of various types (e.g., surface mounted devices, flip-chip dies, wire-bonding dies, etc.) and more laminate passive structures 12, and each laminate passive structure 12 may cap fewer or more top components 16 or may not cap any top components 16 on the top side of the module substrate 14. Additionally, the multi-level SIP module 10 may include more bottom components 18 of various types (e.g., surface mounted devices, flip-chip dies, wire-bonding dies, passive components without stand-off, etc.) and fewer or more bump structures 20, formed in different layouts on the bottom side of the module substrate 14. Furthermore, the multi-level SIP module 10 may be a single-sided module instead of a double-sided module, so that the bottom component 18 and the bump structures 20 may be omitted.

In detail, the module substrate 14 includes a laminate substrate body 14B, which may be composed of prepreg (PPG) layers (not shown for clarity and simplicity), and multiple metal layers 26 alternating vertically with the PPG layers (not shown for clarity and simplicity). In some applications, the laminate substrate body 14B may be formed from a resin-based system with inorganic fillers (e.g. resin coated copper) in place of the PPG layers. The multiple metal layers 26 have a top metal layer 26TL on a top surface of the laminate substrate body 14B, a bottom metal layer 26BL on a bottom surface of the laminate substrate body 14B, and multiple internal metal layers embedded in the laminate substrate body 14B (not shown for clarity and simplicity). For the purpose of this illustration, the top metal layer 26TL includes top metal pads 26TP (for clarity and simplicity, only certain top metal pads are labeled with reference numbers) to accommodate the top components 16 as well as the laminate passive structure 12. Each top metal pad 26TP may have a same or different size with an appropriate shape, such as a circle, square, etc. The top metal layer 26TL may also include other top metal features (not shown for clarity and simplicity), such as top routing lines to connect between the top metal pads 26TP. Similarly, the bottom metal layer 26BL includes bottom metal pads 26BP (for clarity and simplicity, only certain bottom metal pads are labeled with a reference number) to accommodate the bottom component 18 and the bump structures 20. Each bottom metal pad 26BP may have a same or different size with an appropriate shape, such as a circle, square, etc. The bottom metal layer 26BL may also include other bottom metal features (not shown for clarity and simplicity), such as bottom routing lines to connect between the bottom metal pads 26BP. The multiple metal layers 26 are electrically connected through vias and are designed to establish electrical connections (with vias) among the laminate passive structure 12, the top components 16, the bottom component 18, and the bump structures 20. Additionally, these metal layers 26 may also be configured to provide certain passive components (e.g., ground planes, inductors, capacitors, routings, shield planes, etc.). The module substrate 14 may have a thickness between 70 μm and 400 μm.

For a non-limiting example, the two first top components 16-1 are low-profile flip-chip dies with solder balls 30, the second top component 16-2 is a surface mounted device (SMD), and the third top component 16-3 is a flip-chip die with solder balls 32 (for clarity and simplicity, only one solder ball of the first top component 16-1 and one solder ball of the third top component 16-3 are labeled with reference numbers). Herein, the first and third top components, flip-chip dies with solder balls, 16-1 and 16-3 might be designed to provide active components, while the second top component, SMD, 16-2 might be designed to provide a passive component without stand-off. Each top component 16 is attached to the top side of the module substrate 14 on one or more corresponding top metal pads 26TP. In different applications, there might be fewer or more top components 16 attached to the top side of the module substrate 14 via corresponding top metal pads 26TP, respectively. The top components 16 may be other electrical components, such as wire-bonding dies, flip-chip dies with die copper pillars, Silicon (Si) devices, and/or power amplifiers (PAs). The top components 16 might be mounted to the top metal pads 26TP with or without an adhesive material (e.g., the second top component, SMD, 16-2 is mounted to the corresponding top metal pad 26TP with a top adhesive material 34, while the first and third top components, flip-chip dies with solder balls, 16-1 and 16-3 are attached directly to the corresponding top metal pads 26TP).

Referring to the laminate passive structure 12, it is configured to provide one or more passive components (e.g., resistors, capacitors, inductors, transformers, coils, diodes, etc.) as well as a clearance/stand-off space underneath the one or more passive components. Such clearance/stand-off space enables the laminate passive structure 12 to be vertically stacked with certain top components 16 (e.g., the first top components 16-1) and/or improves electrical performance of the one or more passive components realized within the laminate passive structure 12. In addition, since the laminate passive structure 12 provides certain passive components, there might be fewer or no passive components embedded in the module substrate 14, and therefore the count of the metal layers 26 in the module substrate 14 (as well as a thickness of the module substrate 14) may also be reduced. For non-limiting examples, output matching baluns or transformers of power amplifiers, multiplexing circuits, input/output impedance matching for RF components, and/or couplers can be relocated from the module substrate 14 onto the laminate passive structure 12.

The laminate passive structure 12 is desired to be low-profile (e.g., a height H1 between 220 μm and 300 μm, or between 100 μm and 350 μm) and includes a component unit 36, a stiffening layer 38, and copper posts 40, as illustrated in FIG. 1B. Herein, the component unit 36 includes a laminate body 36B composed of PPG layers (not shown) and metal layers 44 alternating vertically with the PPG layers. In order to achieve a low-profile for the final laminate passive structure 12 and to provide targeted passive components, the component unit 36 may include 3~9 metal layers 44 and may have a thickness T1 between 70 μm-220 μm (e.g., top-metal to bottom-metal thickness). For the purpose of this illustration, the component unit 36 includes a top metal layer 44TL positioned about a top side of the component unit 36, a bottom metal layer 44BL positioned about a bottom side of the component unit 36, and an internal metal layer 44IL vertically between the top metal layer 44TL and the bottom metal layer 44BL. The top metal layer 44TL is embedded within the laminate body 36B but not fully covered by the laminate body 36B. In other words, the top metal layer 44TL may be exposed through the laminate body 36B without protruding from a top surface of the laminate body 36B. The laminate body 36B and the top metal layer 44TL share a planarized top plane (i.e., a top surface of the laminate body 36B and a top surface of the top metal layer 44TL are coplanar). In some embodiments, the top metal layer 44TL might be formed by embedded trace substrate (ETS) technology, which allows for very fine feature sizes (e.g. a width of a metal feature can be as small as 5 μm and a pitch between two adjacent metal features can be as small as 8 μm) to form patterned metal features (e.g., inductors/transformers). Additionally, the internal metal layer 44IL is completely embedded in the laminate body 36B and electrically connected to both the top metal layer 44TL and the bottom metal layer 44BL through vias (not shown for clarity and simplicity). Each of the top metal layer 44TL and the internal metal layer 44IL may include one or more metal features (e.g., metal pads, metal traces, etc..), which is designed to provide at least a portion of one passive component (e.g., a resistor, a capacitor, an inductor, a transformer, a coil, a diode, etc..), or multiple passive components and/or achieve electrical connections among these passive components.

The bottom metal layer 44BL is formed on a bottom surface of the laminate body 36B (i.e., protruding from the bottom surface of the laminate body 36B) and includes bottom metal pads 44BP to accommodate the copper posts 40, respectively (only one bottom metal pad is labeled with a reference number for clarity and simplicity). The bottom metal layer 44BL may also include other bottom metal features, such as bottom metal traces 44BT to establish electrical connections among the bottom metal pads 44BP (not shown) and/or between the bottom metal pads 44BP and the passive components provided by the internal metal layer 44IL and the top metal layer 44TL (through vias, not shown). The bottom metal traces 44BT alone or combined with the internal metal layer 44IL may also be configured to provide passive elements (e.g., capacitors, inductors, routing traces, etc.).

In different applications, the component unit 36 may include two or more internal metal layers 44IL, provided that the total thickness of the component unit 36 does not exceed 200 μm. The top metal layer 44TL may be formed on the top surface of the laminate body 36B (i.e., protruding from the top surface of the laminate body 36B), when a total number of the metal layers 44 of the component unit 36 is at least four (i.e., when there are at least two internal metal layers 44IL). Typically, each of the metal layers 44 may have a thickness between 10 μm and 12 μm and may incorporate a variety of metal features, which may vary in horizontal shape, horizontal size, and/or horizontal layouts. The metal layers 44, along with a dielectric in-between (e.g., the PPG layers of the laminate body 36B), are capable of providing one or more passive components, which are electrically connected to the copper posts 40.

Furthermore, when the top metal layer 44TL is exposed through the laminate body 36B (e.g., the top metal layer 44TL is coplanar with the laminate body 36B or the top metal layer 44TL protrudes from the laminate body 36B), the stiffening layer 38 is provided over the top side of the component unit 36 to encapsulate the top metal layer 44TL. The stiffening layer 38 is in contact with the top surface of the laminate body 36B as well as the top metal layer 44TL. The stiffening layer 38 may be a non-conductive protective film with a thickness between 10 μm and 50 μm or between 10 μm and 25 μm, and may be formed from a mold compound, a solder-mask, extra PPG materials, or any other proper material. The stiffening layer 38 is configured to prevent the component unit 36 from being electrically coupled to a shielding structure that covers the laminate passive structure 12 (more details are described below).

Each copper post 40 is in contact with a corresponding bottom metal pad 44BP and extends from a bottom side of the component unit 36 towards a corresponding top metal pad 26TP on the top side of the module substrate 14. Herein, each passive component formed in the component unit 36 is electrically connected to one or more copper posts 40 and is further electrically connected to one or more of the top components 16, the bottom component 18, and the bump structures 20 through the metal layers 26 and the vias of the module substrate 14. In order to achieve a superior electrical connection between each copper post 40 and the corresponding top metal pad 26TP on the top side of the module substrate 14, an end surface of each copper post 40 is covered by a surface finish 46. The surface finish 46 is designed to ensure that the end surface of each copper post 40 is solderable for adhesion. The surface finish 46 might be formed from gold (Au), silver (Ag), tin (Sn), nickel gold (NiAu), nickel palladium gold (NiPdAu), or any combination thereof. A solder joint 48, applied between the surface finish 46 on each copper post 40 and the corresponding top metal pad 26TP, enables an electrical connection from the copper posts 40 to the top metal layer 26TL of the module substrate 14, and therefore, enables an electrical connection from the passive components formed in the component unit 36 to one or more of the top components 16 mounted on the top metal layer 26TL.

Each copper post 40, along with the corresponding surface finish 46 and the corresponding solder joint 48, may have a same height H2 between 25 μm and 150 μm, so as to provide a stand-off space that is vertically between the component unit 36 and the module substrate 14 and surrounded by the copper posts 40. Each copper post 40 may have a horizontal diameter between 50 μm and 150 μm. For the purpose of this illustration, two top components 16 (e.g., the two flip-chip dies 16-1) are attached to the module substrate 14, underneath the component unit 36 without contacting the component unit 36, and surrounded by the copper posts 40. In order to provide enough clearance for the component unit 36 relative to the top components 16 underneath the component unit 36 and maintain the thinness and reliability of the final multi-level SIP module 10, a gap between the bottom side of the component unit 36 (i.e., the bottom metal layer 44BL) and a top surface of each top component 16 may have a vertical distance D1 between 10 μm and 50 μm, or in some cases between 20 μm and 30 μm. When the vertical distance D1 is too small, there will be technical challenges in filling a mold compound therebetween, which may lead to reliability issues. Additionally, with the sufficient vertical distance D1, the performance of the one or more passive components formed in the component unit 36 may be improved, since a sufficient dielectric is present between the passive components and the top component 16 underneath the component unit 36. In different applications, there might be fewer or more top components 16 with various types covered by the laminate passive structure 12. Herein, the height of each copper post 40 may be determined based on the height of the top components 16 underneath the component unit 36.

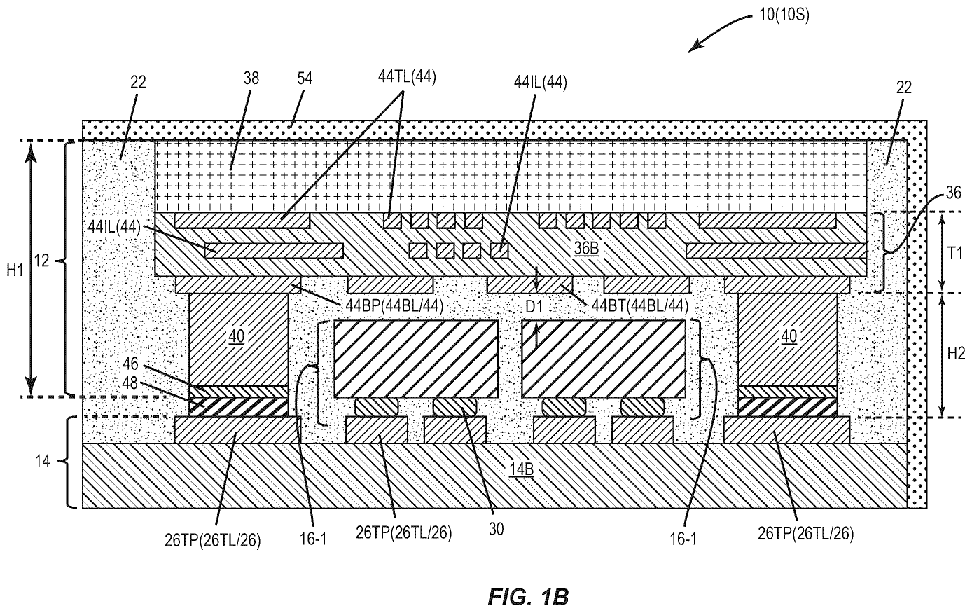

In some embodiments, there might be no top component 16 positioned underneath the component unit 36, as illustrated in FIG. 2. With the height of the copper posts 40, the one or more passive components formed in the component unit 36 are relatively far away from the module substrate 14, which allows more dielectric material between the one or more passive components and the module substrate 14. As such, the electrical performance of the one or more passive components formed in the component unit 36 can be significantly enhanced. A vertical distance D2 between the bottom side of the component unit 36 (i.e., the bottom metal layer 44BL) and the top side of the module substrate 14 (i.e., the top metal layer 26TL) may be between 20 μm and 100 μm. For a non-limiting example, when the top metal layer 44TL of the component unit 36 provides an inductor, omitting the top components 16 underneath the component unit 36 can ensure a higher Q factor for the inductor in the component unit 36 compared to one inductor traditionally embedded in the module substrate 14.

Note that, when the stiffening layer 38 is present in the laminate passive structure 12, a top surface of the laminate passive structure 12 is a top surface of the stiffening layer 38, and a side surface of the laminate passive structure 12 is a combination of a side surface of the component unit 36 and a side surface of the stiffening layer 38. A bottom side of the laminate passive structure 12 is composed of the copper posts 40, portions of the bottom surface of the laminate body 36B, and portions of the bottom metal layer 44BL not covered by the copper posts 40.

The top mold compound 22 is formed on the top side of the module substrate 14 to encapsulate any portion of the top metal layer 26TL not covered by the laminate passive structure 12 or the top components 16, to fully encapsulate each top component 16 and underfill any top component 16 if it is a flip-chip die (e.g., the first top components 16-1 and the third top component 16-3, referring to FIG. 1A). The top mold compound 22 also encapsulates the side surface of the laminate passive structure 12 without covering the top surface (e.g., the top surface of the stiffening layer 38) of the laminate passive structure 12 and encapsulates each copper post 40 of the laminate passive structure 12. Regardless of whether the laminate passive structure 12 is stacked with any top component 16, the top mold compound 22 always fills any gap underneath the component unit 36. When there are one or more top components 16 (e.g., the first top components 16-1) underneath the component unit 36 (referring to FIG. 1B), the mold compound 22 fills the gap between the component unit 36 and the top component 16 underneath the component unit 36 and surrounded by the copper posts 40. When there is no top component 16 underneath the component unit 36 (referring to FIG. 2), the top mold compound 22 fills the gap vertically between the component unit 36 and the module substrate 14 and surrounded by the copper posts 40 (i.e., the stand-off space provided by the copper posts 40). In some embodiments, the top mold compound 22 may fully encapsulate the laminate passive structure 12 including the top surface of the laminate passive structure 12 (not shown). The top mold compound 22 may be an organic epoxy resin system or the like.

When the multi-level SIP module 10 is a double-sided module, the bottom component 18 and the bump structures 20 are attached to the bottom side of the module substrate 14. For a non-limiting example, the bottom component 18 is a flip-chip die, which includes die solder balls 52 (for clarity and simplicity, only one solder ball of the bottom component 18 is labeled with a reference number) attached to corresponding bottom metal pads 26BP on the bottom side of the module substrate 14 (referring to FIG. 1A). The bump structures 20, which protrude from the bottom side of the module substrate 14 and surround the bottom component 18, are copper posts. Each bump structure 20 is formed on a corresponding bottom metal pad 26BP on the bottom surface of the laminate substrate body 14B of the module substrate 14. In different applications, there might be more bottom components 18 attached to the bottom side of the module substrate 14 via corresponding bottom metal pads 26BP. The bottom component 18 may be another electrical component, such as an SMD, a wire-bonding die, a flip-chip die with die copper pillars, an Si device, a PA, or a passive component, while each bump structure 20 may be a solder ball (not shown). The bottom component 18 and the bump structures 20 might be mounted to the bottom metal pads 26BP with or without an adhesive material (not shown). The bottom component 18 and the bump structures 20 might be arranged in a different horizontal layout. The bottom component 18, the bump structures 20, the top components 16, and the laminate passive structure 12 are electrically connected through the metal layers 26 and the vias of the module substrate 14.

In this illustration, the bottom mold compound 24 is formed on the bottom side of the module substrate 14 to encapsulate any portion of the bottom metal layer 26BL not covered by the bottom component 18 or the bump structures 20. The top mold compound 22 also encapsulates sides of the bottom component 18 and sides of each bump structure 20, and underfills the bottom component 18 if it is a flip-chip die. As such, a backside of the bottom flip-chip die 18 and an end surface of each bump structure 20 are exposed through the bottom mold compound 24. In some embodiments, the bottom mold compound 24 may fully encapsulate the bottom component 18 (not shown). The bottom mold compound 24 may be an organic epoxy resin system or the like. The top mold compound 22 and the bottom mold compound 24 may be formed of a same or different material.

Herein, a top surface of the multi-level SIP module 10 is a combination of a top surface of the top mold compound 22 and the top surface of the laminate passive structure 12. If the laminate passive structure 12 is fully encapsulated by the top mold compound 22, the top surface of the multi-level SIP module 10 is the top surface of the top mold compound 22 (not shown). A side surface of the multi-level SIP module 10 is a combination of a side surface of the top mold compound 22, a side surface of the module substrate 14, and a side surface of the bottom mold compound 24 (if it exists). A bottom side of the multi-level SIP module 10 is the bottom side of the module substrate 14 (if the multi-level SIP module 10 is a single sided module, not shown) or is a combination of the bottom surface of the bottom mold compound 24, the backside of the bottom component 18 (if exposed), and the end surface of each bump structure 20 (if the multi-level SIP module 10 is a double side module).

In some embodiments, the multi-level SIP module 10 may be shielded by a module shielding structure 54 to be a shielded multi-level SIP module 10S. The module shielding structure 54 directly and completely covers the top surface and the side surface of the multi-level SIP module 10 without covering the bottom side of the multi-level SIP module 10. Herein and hereafter, completely covering a surface refers to covering at least 99% of such surface. If the stiffening layer 38 is present in the laminate passive structure 12, the module shielding structure 54 is in contact with the top surface of the stiffening layer 38, and the stiffening layer 38 is configured to prevent the module shielding structure 54 from being electrically coupled to the component unit 36. If the top mold compound 22 fully encapsulates the laminate passive structure 12, the module shielding structure 54 is in contact with the top surface of the top mold compound 22, and the certain portion of the top mold compound 22, which is positioned vertically above the component unit 36, is configured to prevent the module shielding structure 54 from being electrically coupled to the component unit 36.

The module shielding structure 54 may include multiple shielding layers, each of which may be formed of copper, aluminum, silver, gold, stainless steel, nickel or other conductive materials. Exemplary implementations of the module shielding structure 54 can be found in U.S. Pat. No. 12,342,518 B2, entitled “COMPARTMENTALIZED SHIELDING OF A MODULE UTILIZING SELF-SHIELDED SUB-MODULES,” which is incorporated herein by reference.

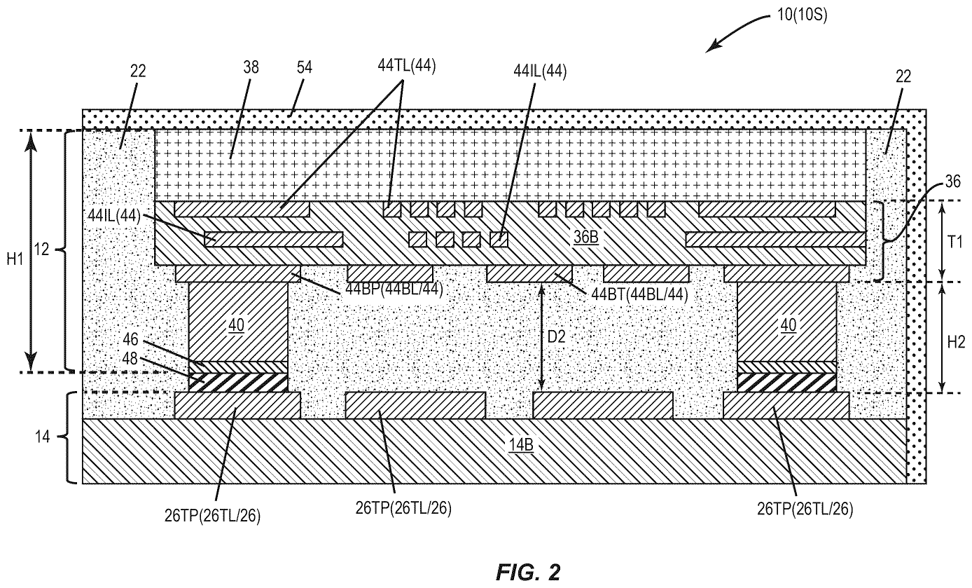

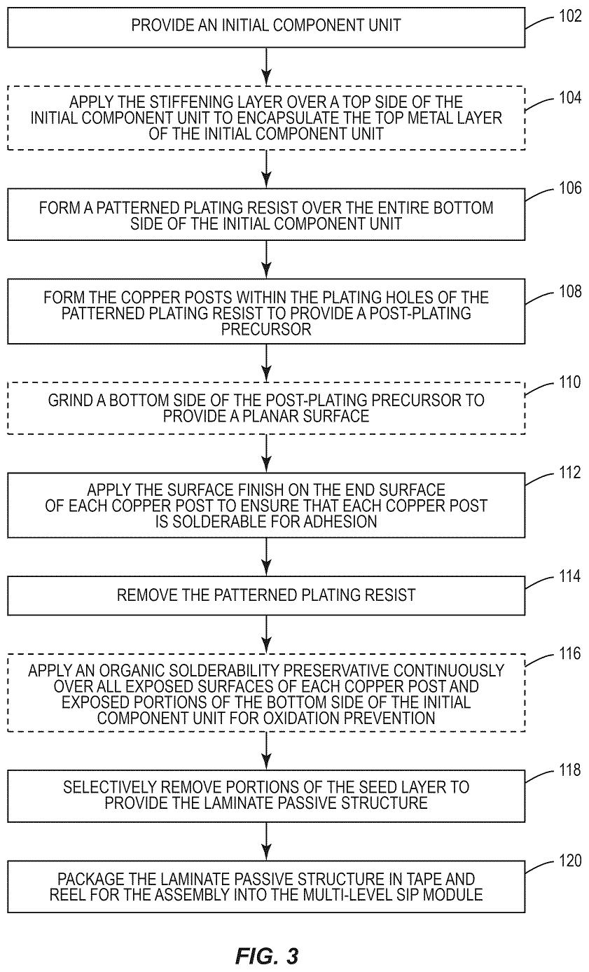

FIG. 3 provides a flow diagram that illustrates an exemplary process for manufacturing the laminate passive structure 12 according to some embodiments of the present disclosure. FIGS. 4-10 illustrate exemplary steps associated with the manufacturing process of the laminate passive structure 12 provided in FIG. 3. Although the exemplary steps are illustrated in a series, the exemplary steps are not necessarily order dependent. Some steps may be done in a different order than that presented. Further, processes within the scope of this disclosure may include fewer or more steps than those illustrated in FIGS. 4-10.

Initially, an initial component unit 36_IN is provided as illustrated in FIG. 4 (step 102). The initial component unit 36_IN is slightly different from the component unit 36 in the final laminate passive structure 12. Besides the laminate body 36B and the metal layers 44, the initial component unit 36_IN further includes a seed layer 56, which is designed to connect each metal feature of the bottom metal layer 44BL. In order to achieve a low-profile for the final laminate passive structure 12 and to provide targeted passive components, the initial component unit 36_IN may include 3~9 metal layers 44 and has a thickness T1 between 70 μm and 220 μm (from the top metal layer 44TL to the bottom metal layer 44BL). The initial component unit 36_IN and the final component unit 36 have the same thickness T1. The top metal layer 44TL is embedded within the laminate body 36B and may share the same planarized top plane with the laminate body 36B (i.e., the top metal layer 44TL is exposed through the laminate body 36B without protruding from the top surface of the laminate body 36B), while the bottom metal layer 44BL is formed over the bottom surface of the laminate body 36B (i.e., protruding from the bottom surface of the laminate body 36B). Herein, the embedded top metal layer 44TL may be formed by the ETS technology, which allows for very fine feature sizes to form patterned metal features (e.g., inductors/transformers). The seed layer 56 is a continuous conductive layer that extends over the entire bottom surface of the laminate body 36B and is designed to connect each metal feature of the bottom metal layer 44BL. As such, a bottom side of the initial component unit 36_IN is composed of a bottom surface of the seed layer 56 and protrusions of the bottom metal layer 44BL.

In addition, the metal layers 44 may also include one or more internal metal layers 44IL, which are completely embedded in the laminate body 36B and electrically connected to both the top metal layer 44TL and the bottom metal layer 44BL through vias (not shown for clarity and simplicity). The top metal layer 44TL and the one or more internal metal layers 44IL, each includes various metal features (e.g., metal pads, metal traces, etc..), which are designed to provide passive components (e.g., resistors, capacitors, inductors, transformers, coils, diodes, etc..) and/or achieve electrical connections among these passive components. The bottom metal layer also includes various metal features to accommodate the copper posts 40 (e.g., the bottom metal pads 44BP), to establish electrical connections among the bottom metal pads 44BP (not shown) and/or between the bottom metal pads 44BP and the passive components provided by the internal metal layer 44IL and the top metal layer 44TL (through vias, not shown). The bottom metal traces 44BT alone or combined with the internal metal layer 44IL may also be configured to provide passive components (e.g., resistors, capacitors, inductors, transformers, coils, diodes, etc.).

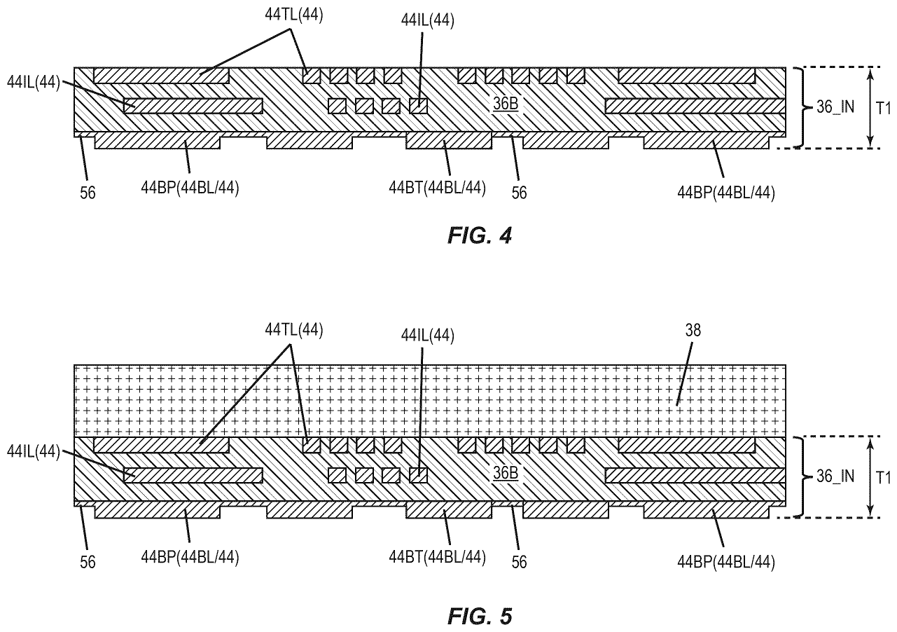

Optionally, the stiffening layer 38 may be applied over a top side of the initial component unit 36_IN to encapsulate the top metal layer 44TL that is exposed through the laminate body 36B (step 104), as illustrated in FIG. 5. The stiffening layer 38 may be in contact with the top surface of the laminate body 36B as well as the top metal layer 44TL. The stiffening layer 38 may be a non-conductive protective film with an initial thickness between 10 μm and 100 μm. The stiffening layer 38 can be thinned after the final laminate passive structure 12 is assembled into the multi-level SIP module 10, therefore, the initial thickness of the stiffening layer 38 may be relatively thick to provide support to the final laminate passive structure 12 during a subsequent module molding step (more details are described below). The stiffening layer 38 may be formed from a mold compound, a solder-mask, extra PPG materials, or any other proper material.

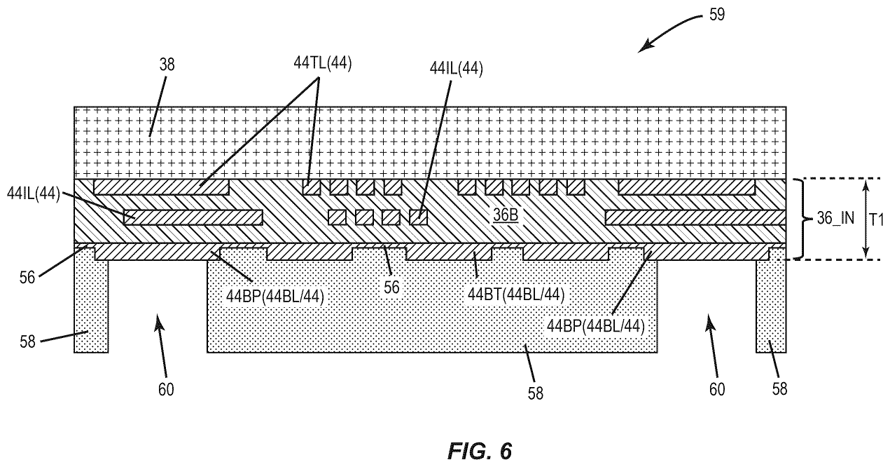

Next, a patterned plating resist 58 is formed over the entire bottom side of the initial component unit 36_IN to provide a plating precursor 59 (step 106), as illustrated in FIG. 6. Herein, the patterned plating resist 58 is designed to define locations of the copper posts 40 that will subsequently be formed. The patterned plating resist 58 includes a number of plating holes 60, through each of which a portion of a corresponding bottom metal pad 44BP (used to form one copper post 40) is exposed, while the remaining portions of the bottom side of the initial component unit 36_IN are fully covered by the patterned plating resist 58. Each plating hole 60 may have a horizontal diameter between 50 μm and 150 μm and a depth between 25 μm and 200 μm, and a pitch between two adjacent plating holes 60 may be as small as 40 μm. Note that since the seed layer 56 extends over the entire bottom surface of the laminate body 36B, the seed layer 56 is exposed (i.e., not covered by the patterned plating resist 58) at a side of the initial component unit 36_IN. The patterned plating resist 58 may be formed from a polymer that can be polymerized with exposure to radiation of UV light.

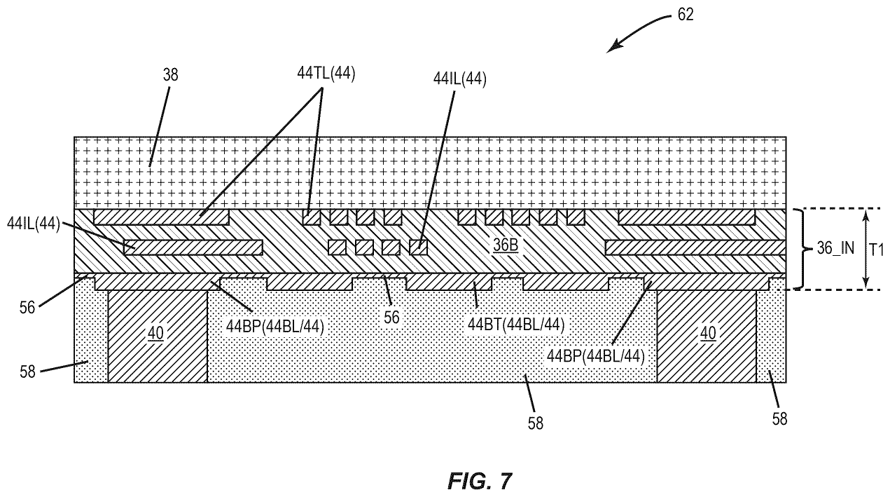

FIG. 7 illustrates formation of the copper posts 40 within the plating holes 60 of the patterned plating resist 58, respectively, to provide a post-plating precursor 62 (step 108). Herein, the copper posts 40 may be formed by an electrolytic copper plating process, during which the plating precursor 59 is immersed in a plating material (including copper) and utilizes the continuous seed layer 56 connected to a voltage source. As such, the bottom metal pads 44BP, which are connected by the seed layer 56 and exposed through the plating holes 60 of the patterned plating resist 58, function as electrolytic plating seed pads to attract the plating material to gradually fill plating holes 60. During the electrolytic copper plating step, the patterned plating resist 58 protects the remaining portion of the bottom metal layer 44BL (other than the bottom metal pads 44BP), and the stiffening layer 38 protects the top side of the initial component unit 36_IN (e.g., the top metal layer 44TL). An exemplary implementation of the electrolytic copper plating process to form the copper posts can be found in PCT Patent Application Publication No. WO 2025/010222 A1, entitled “COPPER POST DESIGN ON LAMINATE FOR IMPROVED PERFORMANCE AND RELIABILITY,” which is incorporated herein by reference.

After the plating step, each plating hole 60 of the patterned plating resist 58 is filled with one copper post 40, which may have a horizontal diameter between 50 μm and 150 μm and a height between 25 μm and 200 μm. In some applications, the copper posts 40 may have height variations, which could result in surface unevenness in subsequent fabrication steps (e.g., an assembly step on the module substrate 14), and therefore, may lead to component interconnect failures within the final product. Herein, a grinding step (step 110, not shown) may be followed to planarize a bottom side of the post-plating precursor 62. After the grinding step, the end surface of each copper post 40 and a bottom surface of the patterned plating resist 58 are coplanar on the planarized bottom of the post-plating precursor 62.

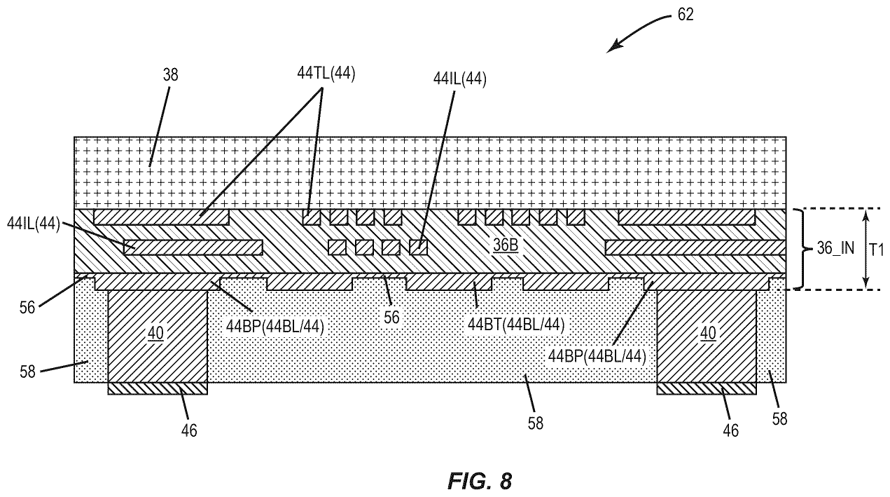

To ensure that the end surface of each copper post 40 is solderable for a subsequent adhesion/assembly step, the surface finish 46 is applied on the end surface of each copper post 40 (step 112), as illustrated in FIG. 8. The surface finish 46 might be an electroless surface finish, such as electroless nickel immersion gold (ENIG), electroless nickel electroless palladium immersion gold (ENEPIG), and any suitable finish formed from Au, Ag, Sn, NiAu, NiPdAu, organic solderability preservative (OSP), or any combination thereof.

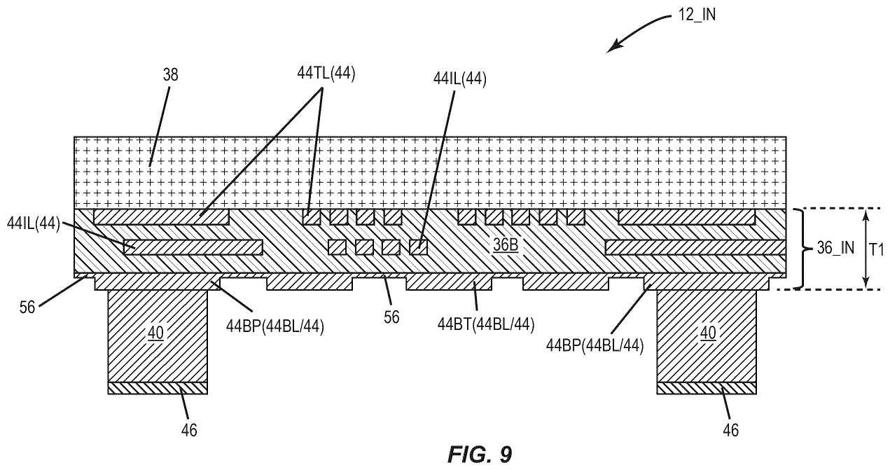

After the surface finish 46 is applied to each copper post 40, the patterned plating resist 58 is removed (step 114), as illustrated in FIG. 9. The copper posts 40 protrude from the bottom side of the initial component unit 36_IN. Certain metal features of the bottom metal layer 44BL other than the bottom metal pads 44BP (e.g., the bottom metal trace 44BT) as well as the seed layer 56 are also exposed at the bottom side of the initial component unit 36_IN. The patterned plating resist 58 may be removed by chemical stripping. In some applications, after removal of the patterned plating resist 58, an OSP may be applied continuously over all exposed surfaces of each copper post 40 (including the surface finish 46) and exposed portions of the bottom side of the initial component unit 36_IN for oxidation prevention (step 116, not shown).

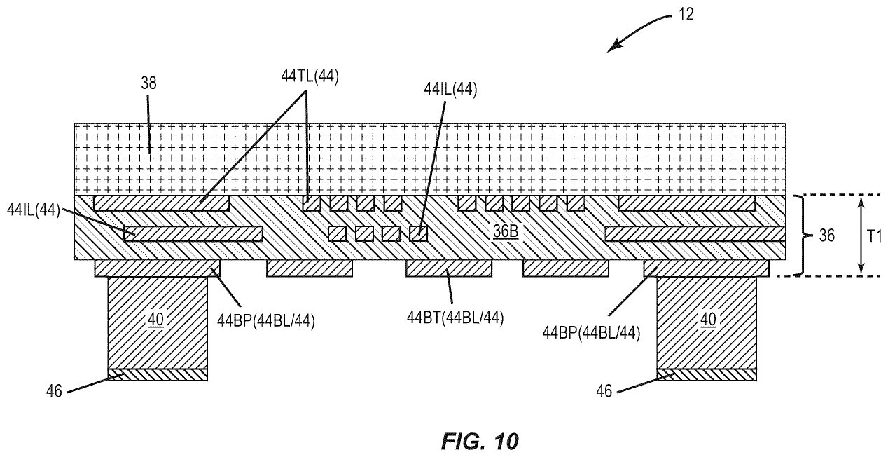

Herein, since each metal feature of the bottom metal layer 44BL is connected by the seed layer 56, and the copper posts 40 are directly formed over the corresponding bottom metal pads 44BP, respectively, the copper posts 40 are also electrically connected to each other by the seed layer 56. FIG. 10 illustrates an etching step (step 118), in which the metal features (e.g., the bottom metal pads 44BP and the bottom metal trace 44BT) of the bottom metal layer 44BL are separated by selectively etching portions of the seed layer 56 therebetween (and selectively etch the continuous OSP, if present), and consequently, the copper posts 40 plated over the bottom metal pads 44BP are also separated from each other. After this etching step, the initial component unit 36_IN is converted into the component unit 36, and the laminate passive structure 12 is completed.

Note that if the stiffening layer 38 is not present in the previously described steps of forming the laminate passive structure 12, the stiffening layer 38 may be applied over the top side of the component unit 36 after selective removal of the portions of the seed layer 56 (not shown). Lastly, the laminate passive structure 12 may be packaged in tape and reel for the assembly into the multi-level SIP module 10 (step 120, not shown).

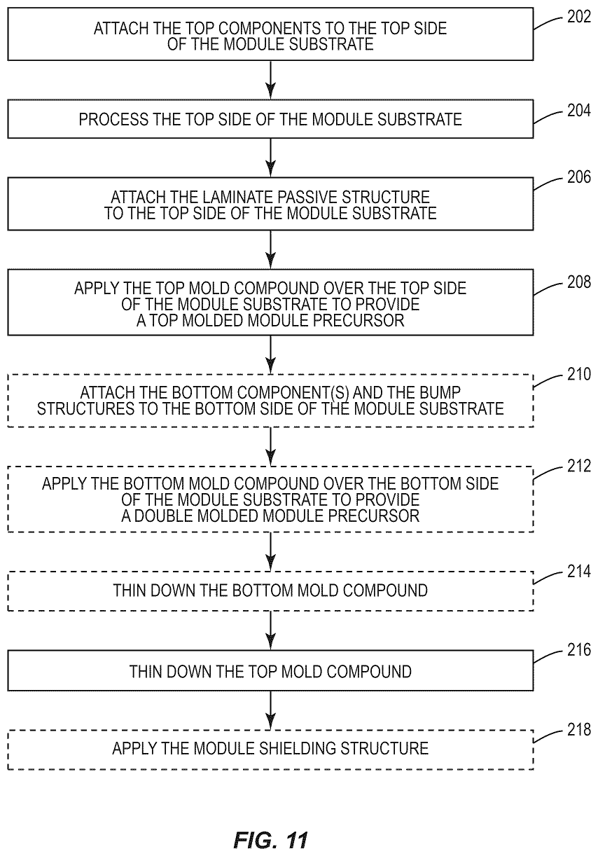

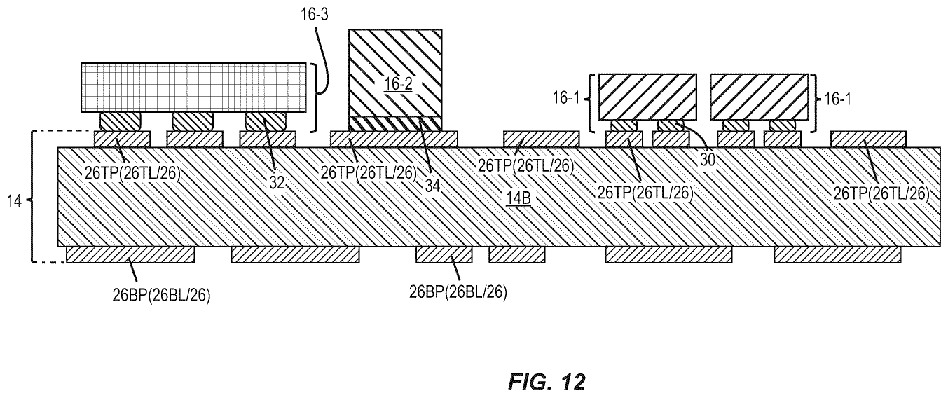

FIG. 11 provides a flow diagram that illustrates an exemplary process for manufacturing the multi-level SIP module 10 using the laminate passive structure 12 according to some embodiments of the present disclosure. FIGS. 12-20 illustrate exemplary steps associated with the manufacturing process of the multi-level SIP module provided in FIG. 11. Although the exemplary steps are illustrated in a series, the exemplary steps are not necessarily order dependent. Some steps may be done in a different order than that presented. Further, processes within the scope of this disclosure may include fewer or more steps than those illustrated in FIGS. 12-20.

Firstly, one or more top components 16 are attached to the top side of the module substrate 14 (step 202), as illustrated in FIG. 12. The module substrate 14 includes the laminate substrate body 14B composed of PPG layers and the multiple metal layers 26 alternating vertically with the PPG layers (not shown for clarity and simplicity). The multiple metal layers 26 include the top metal layer 26TL on the top surface of the laminate substrate body 14B, the bottom metal layer 26BL on the bottom surface of the laminate substrate body 14B, and multiple internal metal layers embedded in the laminate substrate body 14B (not shown for clarity and simplicity). For the purpose of this illustration, the top components 16 include two first top components 16-1, one second top component 16-2, and one third top component 16-3. Each first top component 16-1 is a flip-chip die with the solder balls 30, the second top component 16-2 is an SMD, and the third top component 16-3 is a flip-chip die with the solder balls 32. The top components 16 are mounted to the module substrate 14 by attaching to the corresponding top metal pads 26TP of the top metal layer 26TL with or without an adhesive material (e.g., the second top component, SMD, 16-2 is mounted to the corresponding top metal pad 26TP with the top adhesive material 34, while the first and third top components, flip-chip dies with solder balls, 16-1 and 16-3 are directly attached to the corresponding top metal pads 26TP).

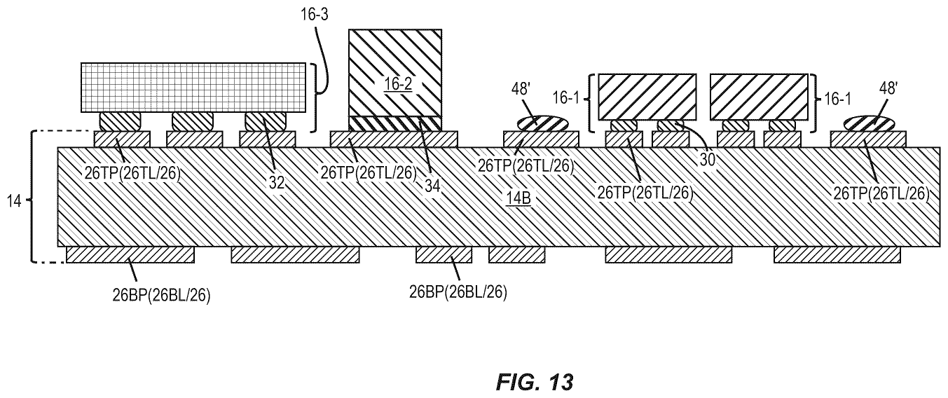

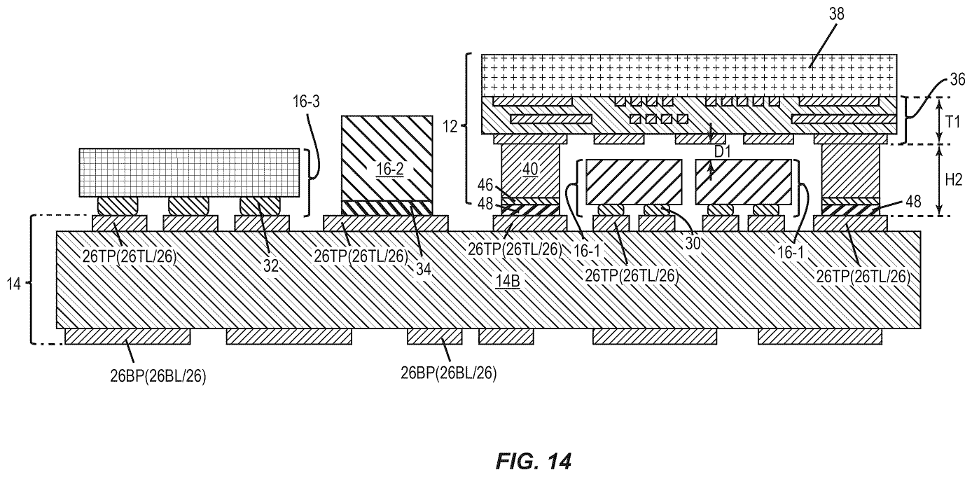

Next, due to variations in the materials used to form the surface finish 46, the top side of the module substrate 14 is processed differently (step 204) in preparation for a subsequent attachment. As illustrated in FIG. 13, certain top metal pads 26TP provided to accommodate the copper posts 40 may have solder paste 48′ applied thereto. Alternatively, the top side of the module substrate 14 may be processed with a screen print flux (not shown). The laminate passive structure 12 is then attached to the top side of the module substrate 14 (step 206), as illustrated in FIG. 14. Herein, the attachment of the laminate passive structure 12 is implemented by surface mount technology (SMT) picking and placing the laminate passive structure 12 from tape and reel onto the corresponding top metal pads 26TP of the top metal layer 26TL and reflowing the solder paste 48′. As such, the surface finish 46 of each copper post 40 is in contact with the solder paste 48′ on the corresponding top metal pad 26TP. After the reflowing process, the solder paste 48′ is converted into the solder joint 48, which securely connects each copper post 40 of the laminate passive structure 12 to the corresponding top metal pad 26TP of the module substrate 14. Notice that if OSP is used in or applied over the surface finish 46, OSP is typically consumed during the reflowing process (not shown).

For the purpose of this illustration, the laminate passive structure 12 caps the first top components 16-1, which are positioned vertically between the module substrate 14 and the component unit 36 and surrounded by the copper posts 40. In different applications, there might be more laminate passive structures 12 attached to the module substrate 14, and each laminate passive structure 12 may not cap any top components 16 or may cap more top components 16 on the top side of the module substrate 14. If there is at least one top component 16 positioned vertically between the module substrate 14 and the component unit 36, the gap between the bottom side of the component unit 36 (i.e., the bottom metal layer 44BL) and the top surface of each top component 16 may have a vertical distance D1 between 10 μm and 50 μm, or in some cases between 20 μm and 30 μm. In other words, each copper post 40, along with the corresponding surface finish 46 and the corresponding solder joint 48 has a height H2, which is approximately 10 μm to 50 μm or 20 μm to 30 μm greater than the height of the at least one top component 16. Herein, with a sufficient vertical distance D1, the performance of the one or more passive components formed in the component unit 36 may be improved. It is because the gap with the sufficient vertical distance D1 allows sufficient dielectric material to be filled between the passive components and the top component 16 underneath the component unit 36.

In some embodiments, when there is no top component 16 positioned underneath the component unit 36, with the height H2 of the copper post 40, along with the corresponding surface finish 46 and the corresponding solder joint 48, the one or more passive components formed in the component unit 36 are relatively far away from the module substrate 14 (referring back to FIG. 2). As such, the electrical performance of the one or more passive components formed in the component unit 36 can be significantly enhanced by allowing a large amount of dielectric material to be filled between the one or more passive components and the module substrate 14.

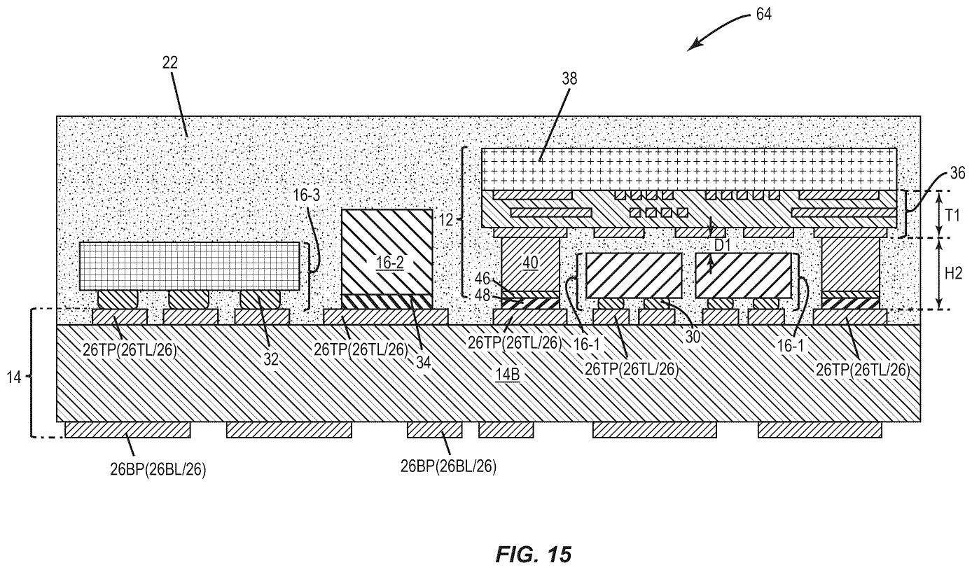

After cleaning residue on the top side of the module substrate 14, the top mold compound 22 is applied over the top side of the module substrate 14 to provide a top molded module precursor 64 (step 208), as illustrated in FIG. 15. The top mold compound 22 encapsulates any portion of the top metal layer 26TL not covered by the laminate passive structure 12 or the top components 16, fully encapsulates each top component 16 (underfills any top component 16 if it is a flip-chip die), fully encapsulates the laminate passive structure 12, and fills gaps between the laminate passive structure 12 and any top component 16 that is underneath the component unit 36 of the laminate passive structure 12. If there is no top component 16 underneath the component unit 36 of the laminate passive structure 12, the top mold compound 22 fills the gap that is vertically between the component unit 36 and the module substrate 14 and surrounded by the copper posts 40. The top mold compound 22 may be an organic epoxy resin system or the like, and may be applied by various procedures, such as compression molding, sheet molding, overmolding, transfer molding, dam fill encapsulation, and screen print encapsulation. Recall that the stiffening layer 38 over the component unit 36 has a relatively thick initial thickness, such that the stiffening layer 38 helps to prevent the laminate passive structure 12 from becoming deformed during this molding step. A curing process (not shown) is then used to harden the top mold compound 22 depending on which material is used to form the top mold compound 22.

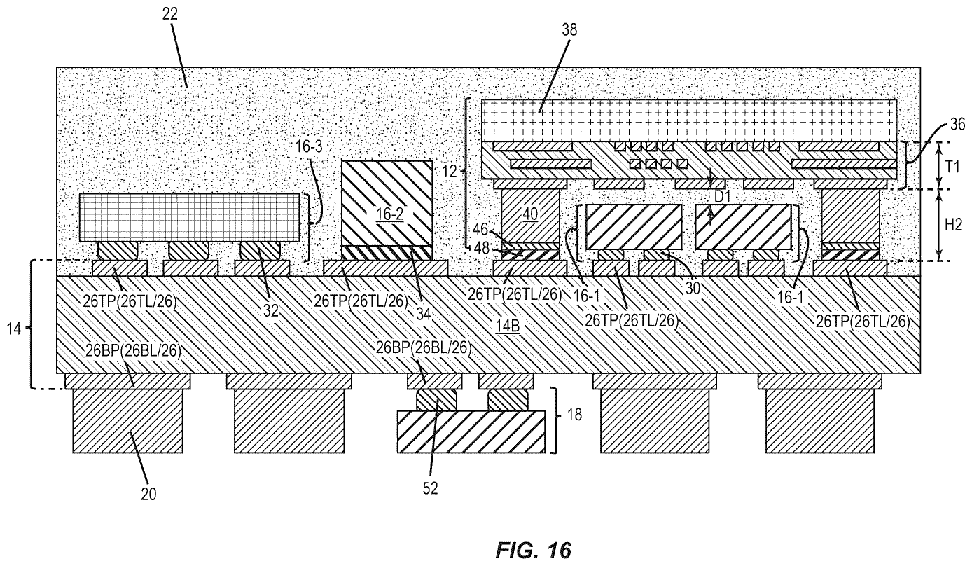

If the final multi-level SIP module 10 is a double-sided structure, one or more bottom components 18 and the bump structures 20 are attached to the bottom side of the module substrate 14 (step 210), as illustrated in FIG. 16. For the purpose of this illustration, there is only one bottom component 18 mounted to the module substrate 14 and surrounded by the bump structures 20. The bottom component 18 is a flip-chip die, which includes the die solder balls 52 attached to the corresponding bottom metal pads 26BP of the bottom metal layer 26BL, while each bump structure 20 is a copper post, which is formed on a corresponding bottom metal pad 26BP of the bottom metal layer 26BL and protrudes from the bottom side of the module substrate 14. In different applications, there might be more bottom components 18 attached to the bottom side of the module substrate 14 via the corresponding bottom metal pads 26BP. The bottom component 18 may be another electrical component, such as an SMD, a wire-bonding die, a flip-chip die with die copper pillars, an Si device, a PA, or a passive component, and each bump structure 20 may be a solder ball (not shown). The bottom component 18 and the bump structures 20 might be attached to the bottom metal pads 26BP with or without an adhesive material (not shown). The bottom component 18 and the bump structures 20 might be arranged in a different horizontal layout. The bottom component 18, the bump structures 20, the top components 16, and the laminate passive structure 12 are electrically connected through the metal layers 26 and the vias (not shown) of the module substrate 14.

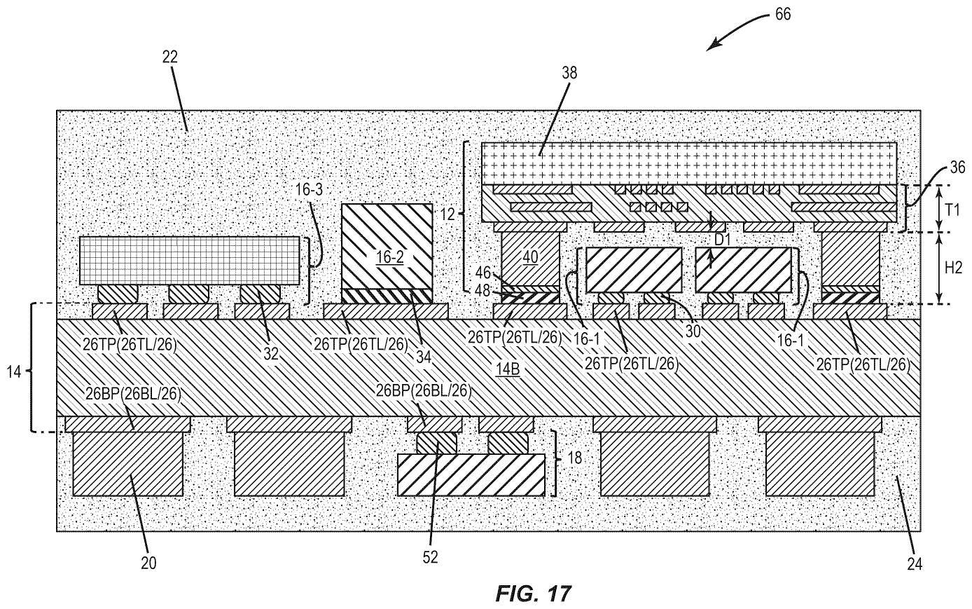

After cleaning residue on the bottom side of the module substrate 14, the bottom mold compound 24 is applied over the bottom side of the module substrate 14 to provide a double molded module precursor 66 (step 212), as illustrated in FIG. 17 (if the final multi-level SIP module 10 is a single sided module, this step will be omitted). The bottom mold compound 24 encapsulates any portion of the bottom metal layer 26TL not covered by the bottom component 18 or the bump structures 20, fully encapsulates the bottom component 18 (underfills the bottom component 16 if it is a flip-chip die), and fully encapsulates each bump structure 20. The bottom mold compound 24 may be an organic epoxy resin system or the like, and may be formed of a same material as or a different material from the top mold compound 22. The bottom mold compound 24 may be applied by various procedures, such as compression molding, sheet molding, overmolding, transfer molding, dam fill encapsulation, and screen print encapsulation. A curing process (not shown) is then used to harden the bottom mold compound 24 depending on which material is used to form the bottom mold compound 24.

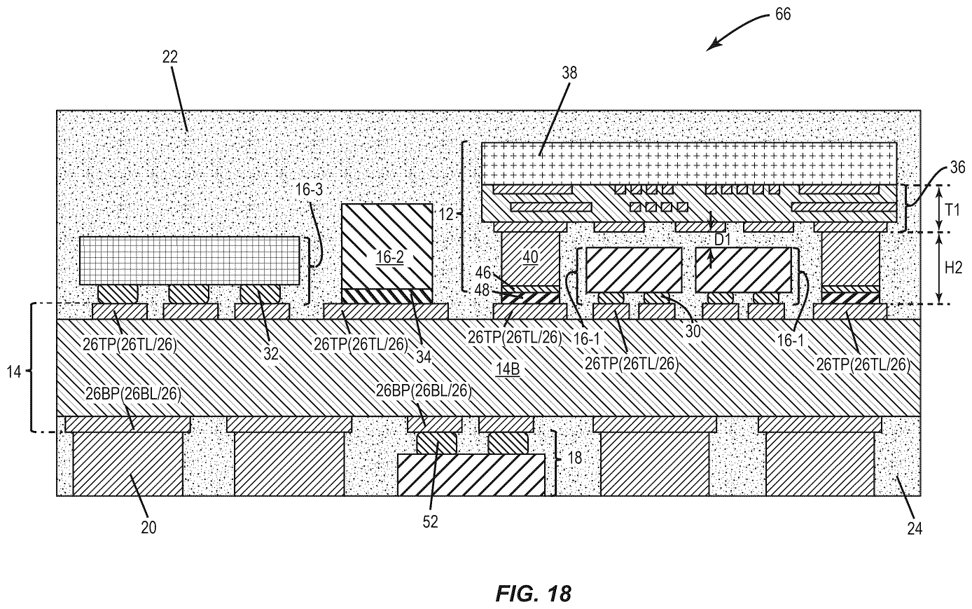

The bottom mold compound 24 is then thinned down to expose each bump structure 20 through the bottom mold compound 24 (step 214), as illustrated in FIG. 18. The thinning step may be done with a grinding process. If the bottom component 18 is a silicon-based flip-chip die, the bottom component 16 can also be ground at the same time as the bottom mold compound 24 until each bump structure 20 is exposed through the bottom mold compound 24. After the thinning step, the side surface of the bottom component 18 and the side surface of each bump structure 20 are still encapsulated by the bottom mold compound 24. In some embodiments, the backside of the bottom component 18 may be exposed through the bottom mold compound 24 and may share a same flat bottom plane with the bottom mold compound 24 and each bump structure 20. In some applications, the bottom component 18 may be shorter than the bump structures 20, such that, after the thinning step, the bottom component 18 is still fully encapsulated by the bottom mold compound 24. Alternatively, this thinning step is omitted, if the end surface of each bump structure 20 is always exposed during the molding process of the bottom mold compound 24.

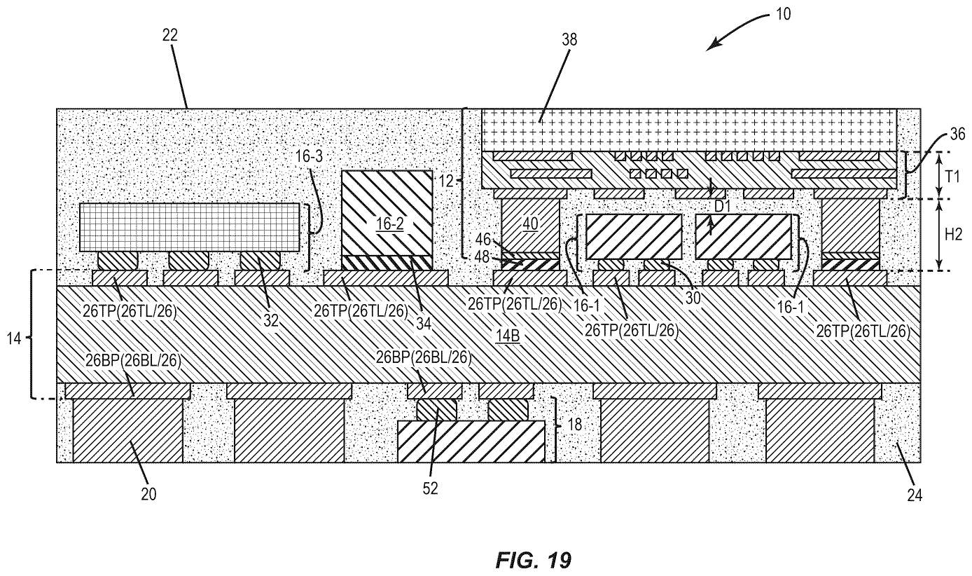

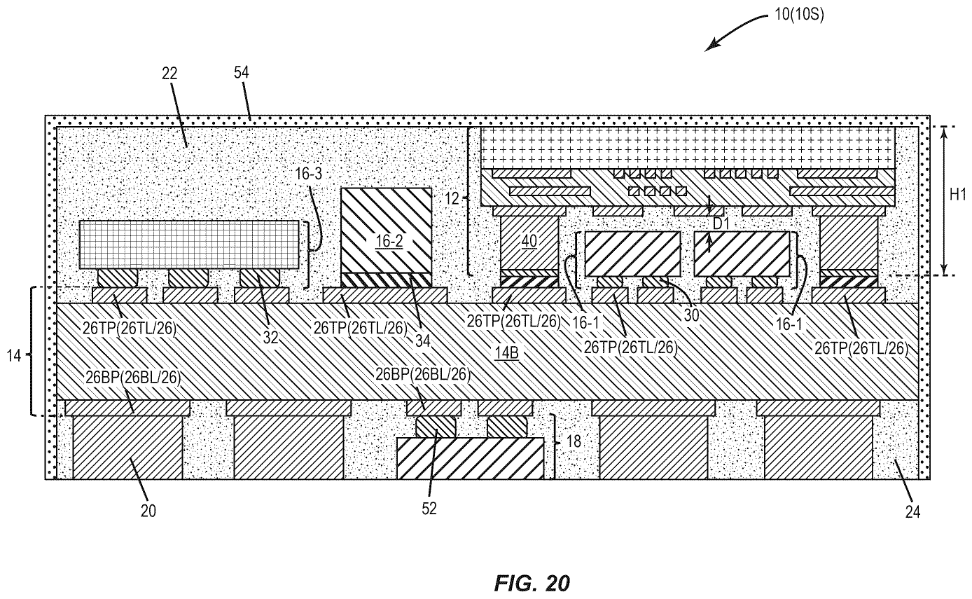

Next, the top mold compound 22 of the double molded module precursor 66 is thinned down to provide the multi-level SIP module 10 with a target thickness (step 216), as illustrated in FIG. 19. The top mold compound 22 is thinned down at least until the stiffening layer 38 of the laminate passive structure 12 is exposed. Recall that the stiffening layer 38 may have a relatively thick initial thickness, such that the stiffening layer 38 may also be thinned down (without complete removal) at the same time as the top mold compound 22 to meet the final module thickness target. The thinning step may be done with a grinding process. Typically, each top component 16 has a lower height than the laminate passive structure 12, and therefore, each top component 16 is still encapsulated by the top mold compound 22 after the thinning step. The top surface of the multi-level SIP module 10 is the combination of the top surface of the top mold compound 22 and the top surface of the stiffening layer 38 of the laminate passive structure 12. The side surface of the multi-level SIP module 10 is the combination of the side surface of the top mold compound 22, the side surface of the module substrate 14, and the side surface of the bottom mold compound 24 (if present). The bottom side of the multi-level SIP module 10 is the bottom side of the module substrate 14 (if the multi-level SIP module 10 is a single sided module) or is the combination of the bottom surface of the bottom mold compound 24, the backside of the bottom component 18 (if exposed), and the end surface of each bump structure 20 (if the multi-level SIP module 10 is a double sided module). Lastly and optionally, the module shielding structure 54 may be applied to the multi-level SIP module 10 to form the shielded multi-level SIP module 10S (step 218), as illustrated in FIG. 20. The module shielding structure 54 directly and completely covers the top surface and the side surface of the multi-level SIP module 10, while the bottom side of the multi-level SIP module 10 is exposed.

According to aspects disclosed herein, multi-level SIP modules and methods for manufacturing the multi-level SIP modules to achieve a high electronic density, a low-profile, and a small footprint may be provided in or integrated into any processor-based electronics. Examples, without limitation, include a base station, a military application device, a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

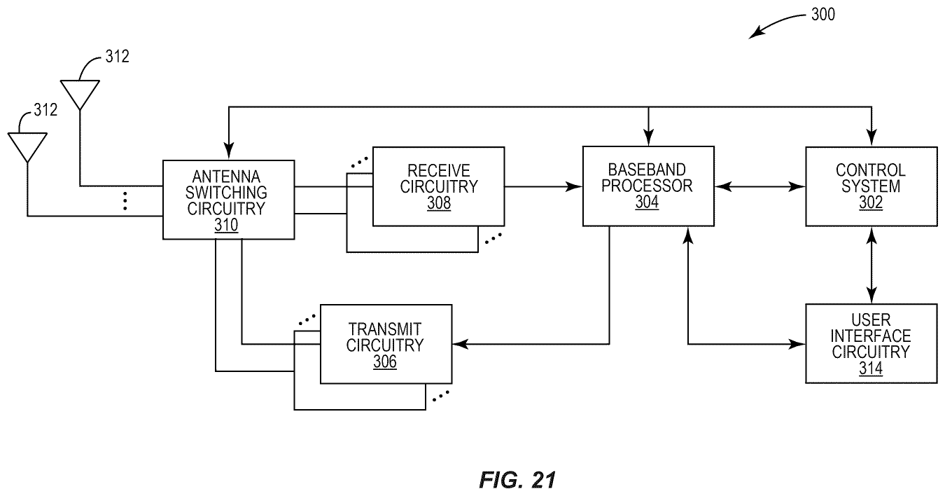

With reference to FIG. 21, the concepts described above may be implemented in various types of communication devices 300, such as those listed in the previous paragraph. The communication device 300 will generally include a control system 302, a baseband processor 304, transmit circuitry 306, receive circuitry 308, antenna switching circuitry 310, multiple antennas 312, and user interface circuitry 314. Herein, at least one or any combination of the control system 302, the baseband processor 304, the transmit circuitry 306, and the receive circuitry 308 may be implemented in the multi-level SIP module 10/10S (e.g. implemented in the one or more top components 16, one or more bottom components 18, and/or the component unit 36) as shown in FIGS. 1A-1B, 2, and 20, and described above.

In a non-limiting example, the control system 302 can be a field-programmable gate array (FPGA) or an application-specific integrated circuit (ASIC), as an example. In this regard, the control system 302 can include at least a microprocessor(s), an embedded memory circuit(s), and a communication bus interface(s). The receive circuitry 308 receives radio frequency signals via the antennas 312 and through the antenna switching circuitry 310 from one or more base stations. A low noise amplifier and a filter of the receive circuitry 308 cooperate to amplify and remove broadband interference from the received signal for processing. Down conversion and digitization circuitry (not shown) will then down convert the filtered, received signal to an intermediate or baseband frequency signal, which is then digitized into one or more digital streams using an analog-to-digital converter(s) (ADC).

The baseband processor 304 processes the digitized received signal to extract the information or data bits conveyed in the received signal. This processing typically comprises demodulation, decoding, and error correction operations, as will be discussed in greater detail below. The baseband processor 304 is generally implemented in one or more digital signal processors (DSPs) and ASICs.

For transmission, the baseband processor 304 receives digitized data, which may represent voice, data, or control information, from the control system 302, which it encodes for transmission. The encoded data is output to the transmit circuitry 306, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 312 through the antenna switching circuitry 310. The multiple antennas 312 and the replicated transmit and receive circuitries 306, 308 may provide spatial diversity. Modulation and processing details will be understood by those skilled in the art.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A multi-level system-in-package (SIP) module comprising:
a module substrate;
a laminate passive structure mounted to a top side of the module substrate, wherein:
the laminate passive structure includes a component unit and a plurality of copper posts;
the component unit includes at least a laminate body, a top metal layer, and a bottom metal layer, wherein the bottom metal layer is positioned about a bottom side of the component unit and protrudes vertically from a bottom surface of the laminate body, while the top metal layer is positioned about a top side of the component unit and configured to provide at least a portion of a passive component; and
the plurality of copper posts is connected to the bottom metal layer on the bottom side of the component unit and extends towards the top side of the module substrate, which provides a stand-off space that is vertically between the component unit and the module substrate; and
at least one top component attached to the top side of the module substrate.

2. The multi-level SIP module of claim 1 wherein the top metal layer is embedded in the laminate body and exposed through the laminate body, and the top side of the component unit is a flat surface composed of a top surface of the laminate body and a top surface of the top metal layer.

3. The multi-level SIP module of claim 2 wherein the top metal layer is formed by an embedded trace substrate (ETS) technology and at least includes patterned metal features.

4. The multi-level SIP module of claim 1 wherein the bottom metal layer at least includes bottom metal pads, each of which is configured to accommodate a corresponding one of the plurality of copper posts and protrudes vertically from the bottom surface of the laminate body.

5. The multi-level SIP module of claim 1 wherein the component unit further includes one or more internal metal layers completely embedded in the laminate body and vertically between the top metal layer and the bottom metal layer.

6. The multi-level SIP module of claim 5 wherein a number of the one or more internal metal layers is between 1 and 7.

7. The multi-level SIP module of claim 1 wherein a thickness of the component unit is between 70 μm and 220 μm.

8. The multi-level SIP module of claim 1 wherein an end surface of each of the plurality of copper posts is covered by a surface finish, which is designed to ensure that the end surface of each of the plurality of copper posts is solderable.

9. The multi-level SIP module of claim 8 wherein the surface finish comprises one or more of gold (Au), silver (Ag), tin (Sn), nickel gold (NiAu), and nickel palladium gold (NiPdAu).

10. The multi-level SIP module of claim 8 wherein each of the plurality of copper posts is connected to a corresponding metal pad at the top side of the module substrate through a solder joint, which is positioned vertically between the surface finish on the end surface of each of the plurality of copper posts and the corresponding metal pad at the top side of the module substrate.

11. The multi-level SIP module of claim 10 wherein a combined height of each of the plurality of copper posts, the surface finish on the end surface of each of the plurality of copper posts, and a corresponding solder joint is the same and is between 25 μm and 150 μm.

12. The multi-level SIP module of claim 1 further comprising a top mold compound, wherein the top mold compound is formed on the top side of the module substrate to fully encapsulate the at least one top component and to surround the laminate passive structure.

13. The multi-level SIP module of claim 12 wherein:
the at least one top component includes a first top component, which is positioned in the stand-off space vertically between the bottom side of the component unit and the top side of the module substrate, and surrounded by the plurality of copper post; and
a gap between the bottom side of the component unit and a top surface of the first top component has a vertical distance between 10 μm and 50 μm and is filled with the top mold compound.

14. The multi-level SIP module of claim 13 wherein the at least one top component further includes a second top component, which is positioned horizontally outside the laminate passive structure.

15. The multi-level SIP module of claim 12 wherein:
the at least one top component is positioned horizontally outside the laminate passive structure;
no electronic component is surrounded by the plurality of copper posts and positioned vertically between the bottom side of the component unit and the top side of the module substrate; and
a gap between the bottom side of the component unit and the top side of the module substrate has a vertical distance between 20 μm and 100 μm and is filled with the top mold compound.

16. The multi-level SIP module of claim 12 wherein:
the laminate passive structure further includes a stiffening layer, which is formed over the component unit to encapsulate the top metal layer of the component unit;
a top surface of the laminate passive structure is a top surface of the stiffening layer, and a side surface of the laminate passive structure is a combination of a side surface of the component unit and a side surface of the stiffening layer; and
the top mold compound at least surrounds and underfills the laminate passive structure without covering the top surface of the laminate passive structure, wherein the laminate passive structure does not vertically extend beyond a top surface of the top mold compound.

17. The multi-level SIP module of claim 16 further comprising a module shielding structure, wherein:
the top surface of the top mold compound and the top surface of the laminate passive structure are coplanar; and
the module shielding structure directly and continuously covers a combination of the top surface of the top mold compound and the top surface of the laminate passive structure, and a combination of a side surface of the top mold compound and a side surface of the module substrate.

18. The multi-level SIP module of claim 1 further comprising at least one bottom component and a plurality of bump structures, wherein the at least one bottom component and the plurality of bump structures are attached to a bottom side of the module substrate, which is opposite from the top side of the module substrate.

19. The multi-level SIP module of claim 18 further comprising a bottom mold compound, wherein:
the bottom mold compound surrounds each of the plurality of bump structures without covering an end surface of each of the plurality of bump structures, wherein a bottom surface of the bottom mold compound and the end surface of each of the plurality of bump structures are coplanar; and
the bottom mold compound at least surrounds the at least one bottom component, wherein the at least one bottom component does not vertically extend beyond the bottom mold compound.

20. The multi-level SIP module of claim 1 wherein the laminate passive structure has a height between 100 μm and 350 μm.

21. A communication device comprising:
a control system;
a baseband processor;
receive circuitry; and
transmit circuitry, wherein at least one or any combination of the control system, the baseband processer, the transmit circuitry, and the receive circuitry is implemented in a multi-level SIP module, which at least includes a module substrate, a laminate passive structure, and at least one top component, wherein:
the laminate passive structure and the at least one top component are attached to a top side of the module substrate;
the laminate passive structure includes a component unit and a plurality of copper posts;
the component unit includes at least a laminate body, a top metal layer, and a bottom metal layer, wherein the bottom metal layer is positioned about a bottom side of the component unit and protrudes vertically from a bottom surface of the laminate body, while the top metal layer is positioned about a top side of the component unit and configured to provide at least a portion of a passive component; and
the plurality of copper posts is connected to the bottom metal layer on the bottom side of the component unit and extends towards the top side of the module substrate, which provides a stand-off space that is vertically between the component unit and the module substrate.

22. A method of manufacturing a multi-level SIP module comprising:
forming a laminate passive structure, which includes a component unit and a plurality of copper posts, wherein:
the component unit includes at least a laminate body, a top metal layer, and a bottom metal layer, wherein the bottom metal layer is positioned about a bottom side of the component unit and protrudes vertically from a bottom surface of the laminate body, while the top metal layer is positioned about a top side of the component unit and configured to provide at least a portion of a passive component; and
the plurality of copper posts is connected to the bottom metal layer on the bottom side of the component unit;
attaching at least one top component to a top side of a module substrate; and
attaching the laminate passive structure to the top side of the module substrate, wherein each of the plurality of copper posts extends from the bottom side of the component unit towards the top side of the module substrate, which provides a stand-off space that is vertically between the component unit and the module substrate.
